(19) United States
(12) Patent Application Publication
(10) Pub. No.: US 2008/0024335 A1
(43) Pub. Date: Jan. 31, 2008

(54) Local Erasure Map Decoder

(75) Inventors: Alexander Golitschek Edler Von Elbwart, Darmstadt (DE); Christian Wengerter, Kleinheubach (DE)

Correspondence Address: STEVENS, DAVIS, MILLER & MOSHER, LLP, 1615 L. STREET N.W., SUITE 850, WASHINGTON, DC, 20036, US

(73) Assignee: Matsushita Electric Industrial Co., LTD, Osaka (JP)

(21) Appl. No.: 10/593,087

(22) PCT Filed: Mar. 22, 2004
(86) PCT No.: PCT/EP04/03017

§ 371 Date: Sep. 15, 2006

(51) Int. Cl. H03M 7/00

(52) U.S. Cl. 341/107

(57) ABSTRACT

The present invention relates to a method for decoding at least one codeword, the at least one codeword having receive codeword been generated by an encoder comprising a structure providing a code representable by a set of branch transitions in a trellis diagram. Further, the present invention provides a respective decoder, as well as a mobile station and a base station in a communication network employing the decoder. Moreover a communication system comprising the base stations and mobile stations is provided. To reduce the influence of wrong information in a decoding process the present invention suggests using only a subset of reliable information in the forward and/or backward recursion of a Maximum A-Posteriori (MAP) Algorithm or Max-Log-MAP Algorithm.

### FIELD OF THE INVENTION

The present invention relates to a method for decoding at least one codeword, the at least one codeword having been generated by an encoder comprising a structure providing a code representable by a set of branch transitions in a trellis diagram. Further, the present invention provides a respective decoder, as well as a mobile station and a base station in a communication network employing the decoder. Moreover a communication system comprising the base stations and mobile stations is provided.

### TECHNICAL BACKGROUND

### Shift-Register Coding

Convolutional codes and related codes may be generated by means of one or more cascaded or concatenated shift registers. For matters of simplicity, binary shift registers are considered in the following sections. The binary shift registers are capable of taking the value of either binary 0 or binary 1. When a shift occurs, the content of each register is forwarded to the subsequent register to be its new content. Usually the input to the encoder is used as the new content of the first register.

The output of a binary shift register encoder is usually obtained by modulo-2 additions of several shift register contents prior to shifting. As an illustration, a simple binary shift-register encoder is shown in FIG. 1, where the number of shift registers r=2 and the number of states is M=4. Each shift register is represented by a D, and each modulo-2 addition unit is represented by “+”. Two output bits are obtained from one input bit: The first output bit is identical to the input bit (upper branch), while the second output bit is obtained by modulo-2 addition of the shift register states and the input bit (lower branch).

In FIG. 2 a state-transition diagram for the encoder from FIG. 1 is shown. Each state is represented by the values of the shift register. Each transition is represented by a directed edge. A transition caused by an input bit of zero is denoted by a broken edge, while a transition caused by an input bit of one is denoted by a straight edge. Each edge is further labeled with the input bit followed by the corresponding output bits. An alternative representation of the state transition diagram is a trellis, which is composed of trellis elements as shown in FIG. 3. Further details about shift-register encoding (also known as convolutional encoding) may for example be found in Lin et al., “Error Control Coding: Fundamentals and Applications”, Prentice-Hall Inc., chapter 10.

Shift registers are commonly employed for convolutional codes. Recently, they have also been used in “turbo codes” reaching very low error rates, which make them attractive for communication systems.

Popular decoding algorithms for shift-register codes are for example the Viterbi algorithm and the maximum a-posteriori algorithm. While the former is often used for traditional convolutional codes, the latter is very popular for the decoding of turbo codes due to its soft a-posteriori probability output.

### Maximum A-Posteriori Algorithm

A brief description of the maximum a-posteriori algorithm is provided in the following paragraphs. For brevity, the binary case is considered in more detail. The extension to the non-binary case should impose no problem to those skilled in the art. Generally speaking in the non-binary case event probabilities may usually not be expressed by a log-likelihood ratio. Instead some (possibly logarithmic) absolute probability measure may be used. Evidently, all equations given subsequently involving log-likelihood ratios would have to be changed so that they hold for mentioned absolute probability measures.

A simplifying characteristic of the binary case is that—since there are only two possible events—the event probabilities may be expressed in terms of a log-likelihood ratio (LLR), which is generally defined by

$$LLR = ln \frac{p ( x = 1 )}{p ( x = 0 )} = ln \frac{p ( x = 1 )}{1 - p ( x = 1 )} \qquad Equation 1$$

as the natural logarithm of the ratio of probabilities that x is one of the two possible events.

The following symbols are used throughout this document:

| | |
|---|---|
| k | Information bit index |
| K | Number of information bits in one coded block |
| r | Number of shift registers in the encoder |
| M | Number of states within the encoder |
| Sₖ | State for index k |
| dₖ | information bit number k, either 0 or 1, prior to encoding |
| \hat{d}ₖ | information bit number k, either 0 or 1, after decoding |
| xₖ^{s} | Systematic value for bit dₖ at the output of encoder, −1 or +1 |
| xₖ^{p} | Parity value for bit dₖ at the output of encoder, −1 or +1 |
| xₖ = (xₖ^{s}xₖ^{p}) | Systematic and parity value sequence for bit dₖ at the output of encoder |
| yₖ^{s} | Received value for systematic bit k at the input of decoder |
| yₖ^{p} | Received value for parity bit k at the input of decoder |
| yₖ = (yₖ^{s}yₖ^{p}) | Received systematic and parity bit sequence for information bit k |
| | at the input of decoder |
| γ_{k,i}(yₖ, m′, m″) | Branch transition probability for transit between states m′ and m″, given |
| | the observation of the received codeword yₖ, assuming an |
| | information bit dₖ = i (see explanation of Equation 2) |
| Γₖ(yₖ, m′, m″) | Logarithm of γ_{k,i} |
| αₖ (Sₖ) | Probability measure for being in state Sₖ for information bit k given |
| | the received sequence y₁ . . . yₖ |
| βₖ (Sₖ) | Probability measure for being in state Sₖ for information bit k, |
| | given the received sequence yₖ . . . y_{K} |
| Lⁱ(xₖ^{s}) | Intrinsic (a-priori) probability log-likelihood ratio which is available |
| | for bit xₖ^{s} |
| L^{e}(xₖ^{s}) | Extrinsic probability log-likelihood ratio which is computed for bit |
| | xₖ^{s} |
| L(xₖ^{s}) | Decision (a-posteriori) probability log-likelihood ratio which is |
| | computed for bit xₖ^{s} |

The algorithm has two components commonly referred to as the forward and backward recursion. More specifically, two distributions, αₖ and βₖ are recursively updated. The quantity αₖ(Sₖ) represents the probability measure for being in state Sₖ=m for information bit k, given the received sequence y₁ . . . yₖ. In a similar manner, βₖ(Sₖ) represents the probability measure for being in state Sₖ=m for information bit k, given the received sequence yₖ . . . yₖ.

Both recursions may be defined based on the so-called branch transition probability γ_{k,i}(yₖ, m′, m″). This represents the probability to transit between states m′ and m″ given the observation of the received codeword yₖ, assuming that the information bit causing the transit is dₖ=i. The branch transition probability can be computed as

γ_{k,i}((y^{s}ₖ,y^{p}ₖ),Sₖ₋₁,Sₖ)−q(dₖ=i|Sₖ₋₁,Sₖ)·p(y^{s}ₖ|dₖ=i)·p(y^{p}ₖ|dₖ=i,Sₖ₋₁,Sₖ)·Pr{Sₖ|Sₖ₋₁} Equation 2

The value of q(dₖ=i|Sₖ₋₁,Sₖ) is either one or zero, depending on whether bit i is associated with the transition from state Sₖ₋₁ to state Sₖ or not. Pr{Sₖ|Sₖ₋₁} is the a priori probability of the information bit dₖ. In the context of turbo decoding this probability may be the obtained extrinsic information from another decoder. Other terms can be derived easily by those skilled in the art. For example if no a priori information is available the probabilities may be set equal.

Equation 2 can be simplified by omitting the index i if it is assumed that the γ values exist only for those transitions where q(dₖ=i|Sₖ₋₁,Sₖ)=1. Using this assumption the equation can be rewritten as

γₖ((y^{s}ₖ,y^{p}ₖ),Sₖ₋₁,Sₖ)=p(y^{s}ₖ|x^{s}ₖ)·p(y^{p}ₖ|x^{s}ₖ,Sₖ₋₁,Sₖ)·Pr{Sₖ|Sₖ₋₁} Equation 3

Considering the case in which for each information bit dₖ at the encoder input, there are two coded bits xₖ=(x^{s}ₖx^{p}ₖ) at the output of the encoder, Equation 3 may be further simplified, resulting in a code rate of ½. Furthermore, when considering the binary case, Equation 3 may be further simplified by using logarithmic expressions:

Γₖ((y^{s}ₖ,y^{p}ₖ),Sₖ₋₁,Sₖ)=1 nγₖ((y^{s}ₖ,y^{p}ₖ),Sₖ₋₁,Sₖ) Equation 4

In case of a binary shift-register code, the number of states M can be computed as

M=2^{r} Equation 5

### Initialization

For each branch transition originating in state Sₖ₋₁ ending in state Sₖ the branch transition probability for a BPSK (Binary Phase Shift Keying) AWGN (Additive White Gaussian Noise) case is given by

$${Γ}_{k} ( ( {y}_{k}^{s} , {y}_{k}^{p} ) , {S}_{k - 1} , {S}_{k} ) = \frac{1}{2} \cdot {x}_{k}^{s} \cdot ( {L}^{i} ( {x}_{k}^{s} ) + {L}_{c} {y}_{k}^{s} ) + \frac{1}{2} {L}_{c} {y}_{k}^{p} {x}_{k}^{p} \qquad Equation 6$$

with k running from 1 to K.

Since the last term is used frequently below, Equation 6 may be rewritten as

$$\begin{matrix}\begin{matrix}{Γ}_{k} ( ( {y}_{k}^{s} , {y}_{k}^{p} ) , {S}_{k - 1} , {S}_{k} ) = \frac{1}{2} \cdot {x}_{k}^{s} \cdot ( {L}^{i} ( {x}_{k}^{s} ) + {L}_{c} {y}_{k}^{s} ) + \\ {Γ}_{k}^{e} ( {y}_{k}^{p} , {S}_{k - 1} , {S}_{k} )\end{matrix} & Equation 7 \\ using & \\ {Γ}_{k}^{e} ( {y}_{k}^{p} , {S}_{k - 1} , {S}_{k} ) = \frac{1}{2} {L}_{c} {y}_{k}^{p} {x}_{k}^{p} & Equation 8\end{matrix}$$

L_{c} is a channel scaling factor which may be derived from the signal-to-noise ratio (SNR), and is in this case

$${L}_{c} = \frac{2}{{σ}^{2}} \qquad Equation 9$$

with σ² representing the channel noise variance.

The initial values of αₖ and βₖ may be initialized according to system parameters. For a code which begins and ends in the state m=0, the initializations should be

$$\begin{matrix}{α}_{0} ( {S}_{0} ) = \{ \begin{matrix}0 & for {S}_{0} = 0 \\ - ∞ & else\end{matrix} & Equation 10 \\ and & \\ {β}_{k} ( {S}_{0} ) = \{ \begin{matrix}0 & for {S}_{0} = 0 \\ - ∞ & else\end{matrix} & Equation 11\end{matrix}$$

### Forward Recursion

For each state Sₖ, k running from 1 to K, αₖ may be calculated as

$${α}_{k} ( {S}_{k} ) = ln \frac{{\sum }_{{S}_{k - 1} = 1}^{M} exp ( {α}_{k - 1} ( {S}_{k - 1} ) + {Γ}_{k} ( {y}_{k} , {S}_{k - 1} , {S}_{k} ) )}{\begin{matrix}{\sum }_{{S}_{k} = 1}^{M} {\sum }_{{S}_{k - 1} = 1}^{M} exp ( {α}_{k - 1} ( {S}_{k - 1} ) + \\ {Γ}_{k} ( {y}_{k} , {S}_{k - 1} , {S}_{k} ) )\end{matrix}} \qquad Equation 12$$

### Backward Recursion

For each state Sₖ, k running from K−1 to 0, βₖ may be calculated as

$${β}_{k} ( {S}_{k} ) = ln \frac{\begin{matrix}{\sum }_{{S}_{k + 1} = 1}^{M} exp ( {β}_{k + 1} ( {S}_{k + 1} ) + {Γ}_{k + 1} \\ ( {y}_{k + 1} , {S}_{k} , {S}_{k + 1} ) )\end{matrix}}{\begin{matrix}{\sum }_{{S}_{k} = 1}^{M} {\sum }_{{S}_{k + 1} = 1}^{M} exp ( {β}_{k + 1} ( {S}_{k + 1} ) + \\ {Γ}_{k + 1} ( {y}_{k + 1} , {S}_{k} , {S}_{k + 1} ) )\end{matrix}} \qquad Equation 13$$

### Decoding

A full decoding process may consist of an application of the forward and backward recursion. After these recursions one can update the soft-output decision (i.e. the posteriori probability) of each information bit:

$$\begin{matrix}{L}^{e} ( {x}_{k}^{s} ) = ln \frac{\begin{matrix}{\sum }_{( {m}^{′} , {m}^{′′} ) ∈ {S}^{+}} exp ( {α}_{k - 1} ( {m}^{′} ) + {Γ}_{k}^{e} \\ ( {y}_{k} , {m}^{′} , {m}^{′′} ) + {β}_{k} ( {m}^{′′} ) )\end{matrix}}{\begin{matrix}{\sum }_{( {m}^{′} , {m}^{′′} ) ∈ {S}^{-}} exp ( {α}_{k - 1} ( {m}^{′} ) + {Γ}_{k}^{e} \\ ( {y}_{k} , {m}^{′} , {m}^{′′} ) + {β}_{k} ( {m}^{′′} ) )\end{matrix}} & Equation 14 \\ L ( {d}_{k} ) = {L}_{c} \cdot {y}_{k}^{s} + {L}^{i} ( {x}_{k}^{s} ) + {L}^{e} ( {x}_{k}^{s} ) & Equation 15\end{matrix}$$

In the above equation, S⁺ is the set of ordered pairs (m′,m″) corresponding to all state transitions m′→m″ which are caused by data input dₖ=1. S⁻ is similarly defined for dₖ=0.

$$\begin{matrix}{S}^{+} = \{ ( {m}^{′} , {m}^{′′} ) \vert {m}^{′} {\to }^{{d}_{k} = 1} {m}^{′′} \} & Equation 16 \\ {S}^{-} = \{ ( {m}^{′} , {m}^{′′} ) \vert {m}^{′} {\to }^{{d}_{k} = 0} {m}^{′′} \} & Equation 17\end{matrix}$$

Using Equation 15 the value of the k^{th} transmitted bit can be estimated as

$${{d}^{̑}}_{k} = \{ \begin{matrix}1 & if L ( {d}_{k} ) \geq 0 \\ 0 & if L ( {d}_{k} ) < 0\end{matrix} \qquad Equation 18$$

It should be noted that the extrinsic quantity L^{e} obtained in Equation 14 may be used as intrinsic information for a subsequent decoder. Likewise the quantity Lⁱ in Equation 15 may have been obtained as intrinsic information from the extrinsic information of another decoder.

Those skilled in the art will recognize that both quantities can also be set to proper values in case no information is available from another decoder. Further details about applicability of the algorithm to turbo codes, intrinsic information and extrinsic information are given in Berrou et al., “Near Shannon Limit Error-Correcting Coding and Decoding: Turbo Codes (1)”, Proc. IEEE Int. Conf. On Communications, pp. 1064-1070, May 1993.

### Max-Log-MAP Algorithm

To simplify the calculations involved, Equations 12 and 13 may be approximated and substituted by

$$\begin{matrix}{α}_{k} ( {S}_{k} ) = \frac{{max}_{{S}_{k - 1} = 1 … M} ( {α}_{k - 1} ( {S}_{k - 1} ) + {Γ}_{k} ( {y}_{k} , {S}_{k - 1} , {S}_{k} ) )}{\begin{matrix}{max}_{{S}_{k} = 1 … M} \\ [ {max}_{{S}_{k - 1} = 1 … M} ( {α}_{k - 1} ( {S}_{k - 1} ) + {Γ}_{k} ( {y}_{k} , {S}_{k - 1} , {S}_{k} ) ) ]\end{matrix}} & Equation 19 \\ and & \\ {β}_{k} ( {S}_{k} ) = \frac{\begin{matrix}{max}_{{S}_{k + 1} = 1 … M} ( {β}_{k + 1} ( {S}_{k + 1} ) + {Γ}_{k + 1} \\ ( {y}_{k + 1} , {S}_{k} , {S}_{k + 1} ) )\end{matrix}}{\begin{matrix}{max}_{{S}_{k} = 1 … M} [ {max}_{{S}_{k + 1} = 1 … M} ( {β}_{k + 1} ( {S}_{k + 1} ) + \\ {Γ}_{k + 1} ( {y}_{k + 1} , {S}_{k} , {S}_{k + 1} ) ) ]\end{matrix}} & Equation 20\end{matrix}$$

Likewise the decision variable can be obtained by modifying Equation 14 to

$${L}^{e} ( {x}_{k}^{s} ) = {max}_{( {m}^{′} , {m}^{″} ) ∈ {S}^{+}} ( {α}_{k - 1} ( {m}^{′} ) + {Γ}_{k}^{e} ( {y}_{k} , {m}^{′} , {m}^{″} ) + {β}_{k} ( {m}^{″} ) ) - {max}_{( {m}^{′} , {m}^{″} ) ∈ {S}^{-}} ( {α}_{k - 1} ( {m}^{′} ) + {Γ}_{k}^{e} ( {y}_{k} , {m}^{′} , {m}^{″} ) + {β}_{k} ( {m}^{″} ) ) \qquad Equation 21$$

These approximations may degrade the performance of the decoding however.

As can be seen from the equations for the forward and backward recursion, the information from numerous values is involved which is ultimately derived from the received vector corresponding to the transmitted codeword. In a noisy channel environment, chances are high that several received values carry wrong information, which implies that wrong information can be inferred from these values and propagate through the decoding iterations.

### SUMMARY OF THE INVENTION

It is therefore the object of the present invention is to reduce the influence of such wrong information.

The object is solved by the subject matters of the independent claims. Advantageous embodiments of the present invention are subject matters to the dependent claims.

According to one aspect of the present invention not all information in the forward and/or backward recursion is processed, as it would be required by the respective prior-art equations. According to this embodiment of the present invention some of the terms are excluded instead. The decision, which term/s is/are excluded may for example be determined according to its/their reliability. I.e. a term which would produce degrade the decoding performance when employed in determining the forward and/or backward recursion is omitted from the respective equation.

In one of the different exemplary embodiments of the present invention, a method for decoding at least one codeword, wherein the at least one codeword has been generated by an encoder comprising a structure providing a code representable by a set of branch transitions in a trellis diagram is provided.

According to this embodiment, the method may comprise the steps of initializing a set of branch transition probabilities in the decoder based on the received codeword and the encoder structure, initializing a first probability distribution and a second probability distribution according to the initial state of the encoder used to encode the at least one codeword, recalculating the values of the first probability distribution based on the initial values of the first probability distribution and the set of branch transition probabilities using a recursive algorithm, recalculating the values of the second probability distribution based on the initial values of the second probability distribution and the set of branch transition probabilities using a recursive algorithm, and reconstructing a decoded codeword based on the received codeword and an extrinsic probability measure calculated based on the set of branch transition probabilities, the first and the second probability distribution.

In either each of or both steps of recalculating the values of first or second probability distribution a subset of initial values of the first probability distribution or the second probability distribution, respectively, and a subset of the set of branch transition probabilities may be used for recalculating the respective probability distribution. Further, only the values in the subsets fulfilling a predetermined reliability criterion are used.

In a further embodiment, the encoder may be representable by a shift register structure containing at least one of feed-forward mathematic operations and feed-back mathematic operations.

Moreover, in another embodiment of the present invention, the code is suitable for decoding by employing a maximum a-posteriori algorithm.

In a further embodiment of the present invention, the method may further comprise the step of using an intrinsic probability measure to initialize the set of branch transition probabilities.

Another embodiment of the present invention encompasses the step of using an intrinsic probability measure to reconstruct the decoded codeword.

In a further variation of this embodiment, a decoder representable by two separate decoder instances is used for decoding the at least one codeword in a first decoding step and the method may further comprise the step of using the extrinsic probability measure of the first decoder instance as the intrinsic probability measure in the second decoder instance.

In another variation of this embodiment the method further comprises the step of performing a second decoding iteration in the first decoder instance, wherein the decoder instance uses the extrinsic probability measure of the second decoder instance as the intrinsic probability measure.

According to a further embodiment of the present invention the reliability criterion may be based on at least one of channel estimations of a radio channel via which the at least one codeword has been received, the absolute values of the elements of the first and/or second probability distribution, the number of decoding steps performed and a random process. In another variation the reliability criterion may not be fulfilled by an element of the first or the second probability distribution, if the signal to noise ratio for the element and/or the absolute value of the element is below a predetermined threshold value.

Moreover, the present invention provides in another embodiment, a decoder for decoding at least one codeword, wherein the at least one codeword has been generated by an encoder comprising a structure providing a code representable by a set of branch transitions in a trellis diagram.

The decoder may comprise processing means for initializing a set of branch transition probabilities in the decoder based on the received codeword and the encoder structure, initializing a first probability distribution and a second probability distribution according to the initial state of the encoder used to encode the at least one codeword, recalculating the values of the first probability distribution based on the initial values of the first probability distribution and the set of branch transition probabilities using a recursive algorithm, recalculating the values of the second probability distribution based on the initial values of the second probability distribution and the set of branch transition probabilities using a recursive algorithm, and for reconstructing a decoded codeword based on the received codeword and an extrinsic probability measure calculated based on the set of branch transition probabilities, the first and the second probability distribution.

Moreover, the processing means may be adapted to use in either each of or both steps of recalculating the values of the first and second probability distribution a subset of initial values of the first probability distribution or the second probability distribution, respectively, and a subset of the set of branch transition probabilities for recalculating the respective probability distribution, wherein only values are used that fulfill a predetermined reliability criterion.

In a further embodiment of the present invention a decoder comprising means adapted to perform any of the above mentioned decoding methods is provided.

Moreover, another embodiment of the present invention relates to a mobile terminal in a mobile communication system, wherein the mobile terminal may comprise receiving means for receiving at least one codeword, demodulation means for demodulating the at least one received codeword, and a decoder according to one of the embodiments of the present invention.

In another embodiment, the mobile terminal may further comprise encoding means for encoding data in at least one codeword, and transmission means for transmitting the at least one codeword, wherein the at least one transmitted codeword is suitable for decoding according to a decoding methods outlined above.

In a further embodiment of the present invention a base station in a mobile communication system is provided, wherein the base station may comprise receiving means for receiving at least one codeword, demodulation means for demodulating the at least one received codeword, and a decoder according to one of the embodiments of the present invention.

In another embodiment, the base station may further comprise encoding means for encoding data in at least one codeword, and transmission means for transmitting the at least one codeword, wherein the at least one transmitted codeword is suitable for decoding according to a decoding methods outlined above.

Moreover, the according to an even further embodiment provides a mobile communication system comprising at least one base station according to one of the embodiments of the present invention and at least one mobile terminal according to one of the embodiments of the present invention

### BRIEF DESCRIPTION OF THE FIGURES

In the following the present invention is described in more detail in reference to the attached figures and drawings. Similar or corresponding details in the figures are marked with the same reference numerals.

FIG. 1 shows an exemplary a shift-register encoder layout for systematic encoding,

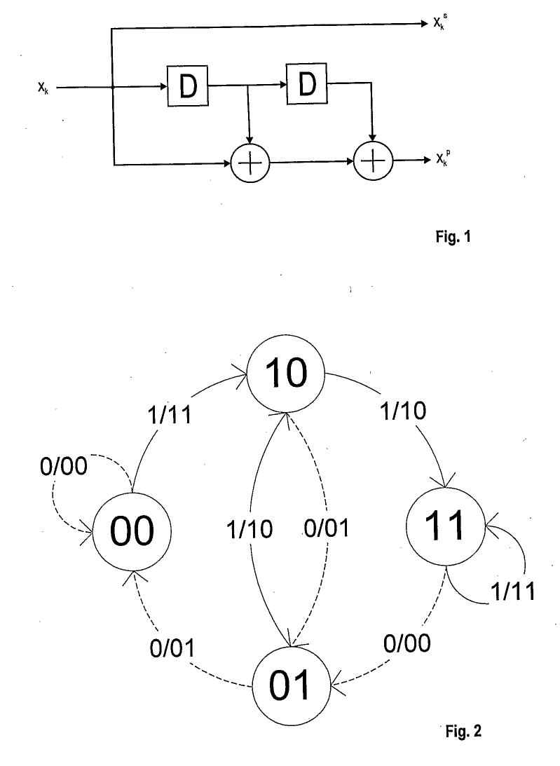

FIG. 2 shows a state transition diagram of the encoder shown in FIG. 1,

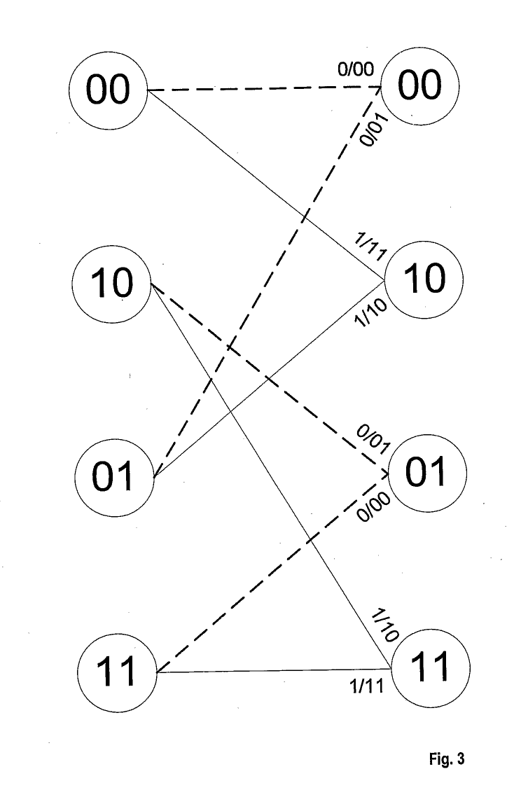

FIG. 3 shows a trellis segment description for the encoder shown in FIG. 1,

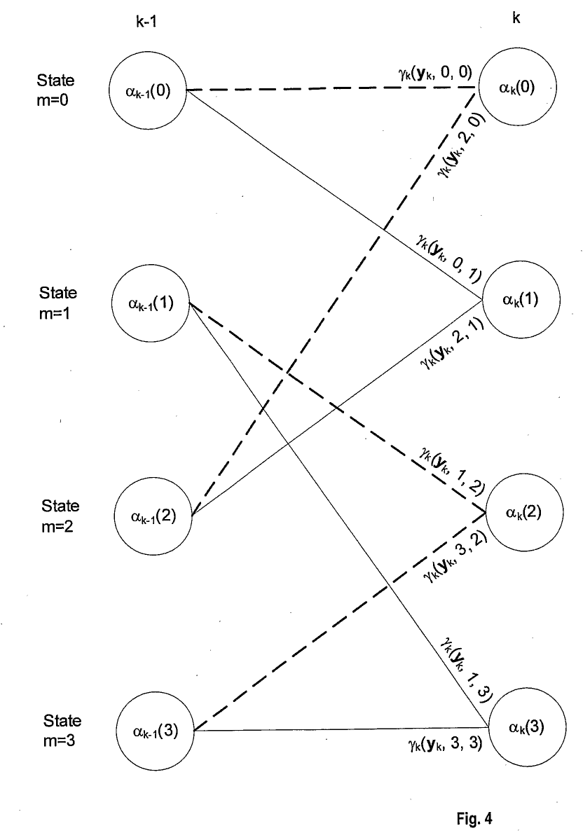

FIG. 4 shows a trellis segment showing variables for the forward recursion,

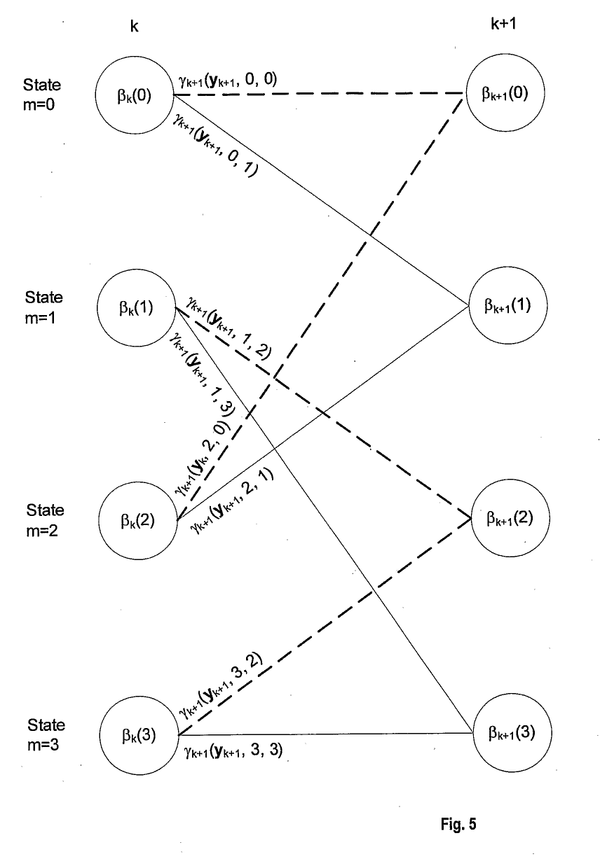

FIG. 5 shows a trellis segment showing variables for the backward recursion,

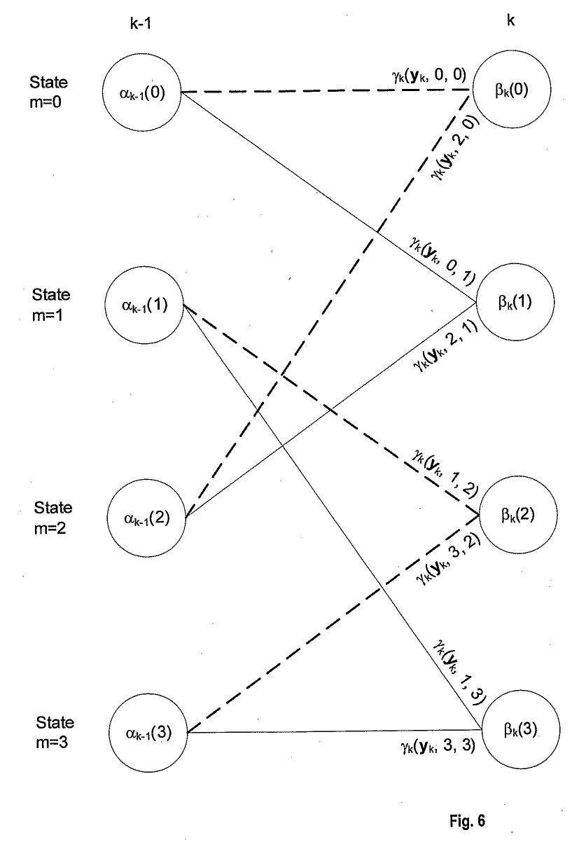

FIG. 6 shows a trellis segment showing variables for the decision,

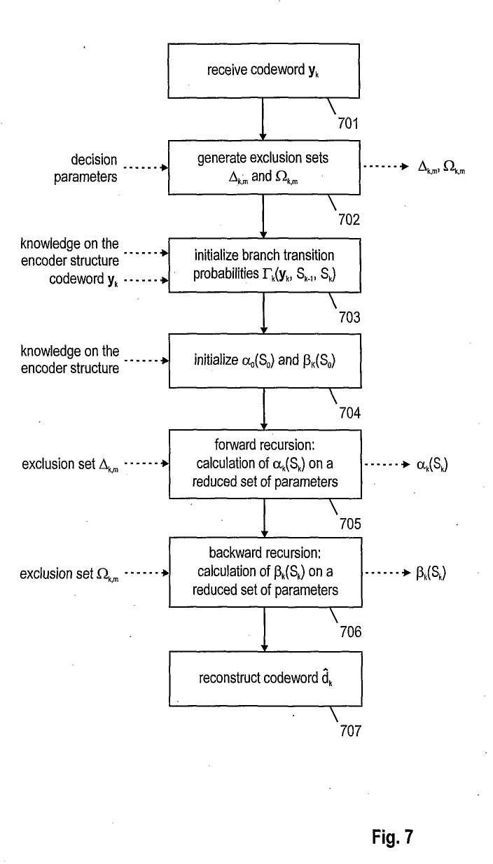

FIG. 7 shows a flowchart of a decoding process according to one embodiment of the present invention,

FIGS. 8 & 9 show flowcharts of a decoding process using the turbo principle according to different embodiments of the present invention,

FIG. 10 shows a transmitter and a receiver unit according to an embodiment of the present invention,

FIG. 11 shows a mobile terminal according to an embodiment of the present invention comprising the transmitter and the receiver shown in FIG. 10,

FIG. 12 shows a base station according to an embodiment of the present invention comprising the transmitter and the receiver shown in FIG. 10, and

FIG. 13 shows an architectural overview of a communication system according to an embodiment of the present invention comprising a mobile terminal shown in FIG. 11 and a base station (Node B) shown in FIG. 12.

### DETAILED DESCRIPTION

In the following paragraphs the expression “xεA\B” denotes “x is element of set A without set B”, which is equivalent to “x is element of set A but not element of set B”.

As outlined in the previous sections, mathematical equations may be solved in the initialization, forward recursion, backward recursion, and decision step of the maximum a-posteriori algorithm (see for example Equations 6, 12, 13, 14 and 15).

Generally these equations contain the following terms terms:
The equation for the initialization contains terms involving y values
The equation for the forward recursion contains terms involving Γ and determined α values
The equation for the backward recursion contains terms involving Γ and determined β values

The numerator of Equation 12 for the forward recursion may be interpreted as a sum of values for state transitions which originate in state Sₖ₋₁ terminate in state Sₖ=m. Therefore the following “forward set” can be defined:

$${T}_{k , m} = \{ {S}_{k - 1} \vert {S}_{k - 1} {}^{{d}_{k} ∈ \{ 0 , 1 \}} {S}_{k} = m \} \qquad Equation 22$$

T_{k,m} is the set of states Sₖ₋₁ where transitions from state Sₖ₋₁ to Sₖare possible by an information bit dₖ.

Therefore

$${α}_{k} ( {S}_{k} = m ) = log \frac{{\sum }_{{m}^{′} ∈ {T}_{k , m}} exp ( {α}_{k - 1} ( {m}^{′} ) + {Γ}_{k} ( {y}_{k} , {m}^{′} , m ) )}{{\sum }_{{m}^{″} = 1}^{M} {\sum }_{{m}^{′} ∈ {T}_{k , {m}^{″}}} exp ( {α}_{k - 1} ( {m}^{′} ) + {Γ}_{k} ( {y}_{k} , {m}^{′} , {m}^{″} ) )} \qquad Equation 23$$

Similarly the numerator of Equation 13 for the backward recursion may be interpreted as a sum of values for state transitions which originate in state Sₖ₊₁ and terminate in state Sₖ=m. Therefore a second “backward set” can be defined:

$${U}_{k , m} = \{ {S}_{k + 1} \vert {S}_{k} = m {}^{{d}_{k} ∈ \{ 0 , 1 \}} {S}_{k + 1} \} \qquad Equation 24$$

U_{k,m} is the set of states Sₖ₊₁ where transitions from state Sₖto Sₖ₊₁ are possible by an information bit dₖ.

Therefore

$${β}_{k} ( {S}_{k} = m ) = log \frac{{\sum }_{{m}^{″} ∈ {U}_{k , m}} exp ( {β}_{k + 1} ( {m}^{″} ) + {Γ}_{k + 1} ( {y}_{k + 1} , {m}^{′} , m ) )}{{\sum }_{{m}^{′} = 1}^{M} {\sum }_{{m}^{″} ∈ {U}_{k , {m}^{′}}} exp ( {β}_{k + 1} ( {m}^{″} ) + {Γ}_{k + 1} ( {y}_{k + 1} , {m}^{′} , {m}^{″} ) )} \qquad Equation 25$$

According to the present invention, exclusion sets Δ_{k,m} and Ω_{k,m} may be additionally defined for the forward and/or backward recursions.

The exclusion set Δ_{k,m} may indicate those elements in the forward set T_{k,m} that do not fulfill a specific reliability criterion and may therefore not be used in the forward recursion step. Likewise, the exclusion set Ω_{k,m} may indicate those elements in the backward set U_{k,m} that do not fulfill a specific reliability criterion and may therefore not be used in the backward recursion step.

Employing the exclusion sets Δ_{k,m} and Ω_{k,m}, the equations may therefore be modified as follows:

### New Forward Recursion

$${α}_{k} ( {S}_{k} = m ) = log \frac{{\sum }_{{m}^{′} ∈ {T}_{k , m} \backslash {Δ}_{k , m}} exp ( {α}_{k - 1} ( {m}^{′} ) + {Γ}_{k} ( {y}_{k} , {m}^{′} , m ) )}{{\sum }_{{m}^{″} = 1}^{M} {\sum }_{{m}^{′} ∈ {T}_{k , {m}^{″}} \backslash {Δ}_{k , {m}^{″}}} exp ( {α}_{k - 1} ( {m}^{′} ) + {Γ}_{k} ( {y}_{k} , {m}^{′} , {m}^{″} ) )} \qquad Equation 26$$

or alternatively simplified to

$${α}_{k} ( {S}_{k} = m ) = \frac{{max}_{{m}^{′} ∈ {T}_{k , m} \backslash {Δ}_{k , m}} ( {α}_{k - 1} ( {m}^{′} ) + {Γ}_{k} ( {y}_{k} , {m}^{′} , m ) )}{{max}_{{m}^{″} = 1 … M} [ \begin{matrix}{max}_{{m}^{′} ∈ {T}_{k , {m}^{″}} \backslash {Δ}_{k , {m}^{″}}} \\ ( {α}_{k - 1} ( {m}^{′} ) + {Γ}_{k} ( {y}_{k} , {m}^{′} , {m}^{″} ) )\end{matrix} ]} \qquad Equation 27$$

### New Backward Recursion

$${β}_{k} ( {S}_{k} = m ) = log \frac{{\sum }_{{m}^{″} ∈ {U}_{k , m} \backslash {Ω}_{k , m}} exp ( {β}_{k + 1} ( {m}^{″} ) + {Γ}_{k + 1} ( {y}_{k + 1} , m , {m}^{″} ) )}{{\sum }_{{m}^{′} = 1}^{M} {\sum }_{{m}^{″} ∈ {U}_{k , {m}^{′}} \backslash {Ω}_{k , {m}^{′}}} exp ( \begin{matrix}{β}_{k + 1} ( {m}^{″} ) + \\ {Γ}_{k + 1} ( {y}_{k + 1} , {m}^{′} , {m}^{″} )\end{matrix} )} \qquad Equation 28$$

or alternatively simplified to

$${β}_{k} ( {S}_{k} = m ) = \frac{{max}_{{m}^{″} ∈ {U}_{k , m} \backslash {Ω}_{k , m}} ( {β}_{k + 1} ( {m}^{″} ) + {Γ}_{k + 1} ( {y}_{k + 1} , m , {m}^{″} ) )}{{max}_{{m}^{′} = 1 … M} [ \begin{matrix}{max}_{{m}^{″} ∈ {U}_{k , {m}^{′}} \backslash {Δ}_{k , {m}^{′}}} \\ ( {β}_{k + 1} ( {m}^{″} ) + {Γ}_{k + 1} ( {y}_{k + 1} , {m}^{′} , {m}^{″} ) )\end{matrix} ]} \qquad Equation 29$$

If both sets Δ_{k,m} and Ω_{k,m} are empty, prior art behavior is replicated. If the exclusion set Δ_{k,m} contains the same elements as the forward set T_{k,m}, then the value of αₖ(Sₖ=m) may not be determined from the recursion formula.

In such a case it may be useful to set the corresponding αₖ(Sₖ=m)=−∞. Likewise βₖ(Sₖ=m)=−∞ may be set when the exclusion set Ω_{k,m} contains the same elements as the backward set U_{k,m}.

In case that for a certain value of k an exclusion set is equal to the forward set for all m=1 . . . M, then αₖ(m) may be set to −1 nM, which means that all states Sₖ=1 . . . M are equally likely. The same applies to the backward set.

Generally the exclusion sets may depend for example on the state index m for which an equation is solved, on the information bit index k for which an equation is solved and/or on the iteration number of the decoding procedure (for example in a turbo decoding context).

### Definition of Exclusion Sets Δ_{k,m} and Ω_{k,m}

As outlined above, the exclusion sets Δ_{k,m} and Ω_{k,m} may be defined in order to exclude data from the equations (or decoding process) which are assumed to be wrong, or which are highly likely to be wrong. If such data is included, the produced output is likely to be wrong as well. Therefore the present invention proposes to neglect such values from the equations to overcome their negative impacts on the decoding output.

As mentioned above, the exclusion sets for the new forward recursion step (see Equation 26 or 27) and backward recursion step (see Equation 28 or 29) may be defined such that unreliable messages are excluded from the calculations. In a further embodiment of the present invention the exclusion sets may for example be defined independently from each other, i.e. an element of exclusion set Δ_{k,m} may not necessarily be element of exclusion set Ω_{k,m}.

Similarly, in another embodiment of the present invention, the exclusion sets Δ_{k,m} and Ω_{k,m} may be set independently in decoding iterations. When increasing the number of iterations, the overall reliability of messages passed may be increased for reasonably good transmission conditions. This may be for example applicable to the decoding of turbo codes, where the extrinsic information exchanged between decoding entities usually-increases in reliability with an increased number of decoding iterations.

Therefore, when increasing the number of iterations the number of elements of the exclusion sets may be reduced, such that at late stages (in terms of iterations) of decoding the exclusion sets may be empty.

In another embodiment of the present invention the exclusion sets may for example depend both on the number of iterations processed so far, as well as on the maximum number of decoding iterations, which may be a parameter given by the communication system. This may allow a gradual reduction of elements in the exclusion sets depending on the progress of iteration steps.

An exemplary list of possible criteria which may be used isolated or in combination for determining the exclusion sets are channel estimation (signal-to-noise ratio), absolute LLR values, iteration number (in turbo decoding context) and/or a random process.

For example a channel estimation criterion allows the definition of exclusion sets according to the perceived quality of received data. The advantage may be that the channel estimation provides a sort of independent side information known at the decoder to estimate the reliability of received coded information. However, the granularity of a channel estimate may be restricted to a segment which consists of several bits, so this measure alone may not be applicable in all situations to define an exclusion set.

An absolute LLR value criterion may allow reliability estimation with a fine granularity. Due to the definition of the LLR value, large absolute values represent a high confidence. Conversely a small absolute value represents a low confidence. Therefore a ranking of absolute LLR values may be used to determine the smallest values for a given equation to be part of the exclusion set. For example, a LLR value criterion may be used alone or in combination with other criteria to determine the elements in the exclusion sets.

A further possible criterion may be a random process criterion. This criterion may be used either alone or in conjunction with other criteria to determine members of the exclusion set. For example, due to channel estimation it may be assumed that 10% of the received information is unreliable. Then for each piece of information there may be a chance of 10% for being member of an exclusion set.

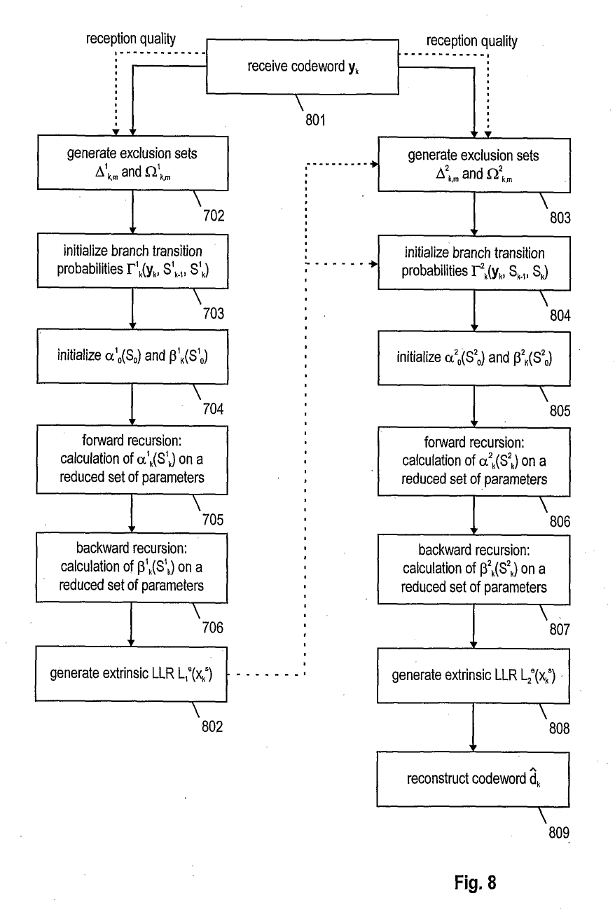

Next, in reference to FIGS. 7, 8 and 9, different embodiments of the present invention will be outlined.

FIG. 7 shows a flowchart of a decoding process according to one embodiment of the present invention. Upon receiving a codeword yₖ via the air interface in step 701, the decoder may generate the exclusion sets Δ_{k,m} and Ω_{k,m} in step 702.

In order to generate the exclusion sets, several different decision parameters may be used to decide which elements should be excluded from the calculations in the forward recursion and/or backward recursion steps 704, 705. For example, receiving means may provide information on the channel quality for the reception of the codeword or individual bits thereof, or may even provide the exclusion sets Δ_{k,m} and Ω_{k,m} to the decoder.

Further, based on the knowledge of the encoder structure and the received codeword yₖ the branch transition probabilities Γ(yₖ,Sₖ₋₁,Sₖ) may be initialized in step 703. Also the probability distributions αₖ and βₖ are initialized in step 704. This may be for example done using the knowledge of the encoder structure used to generate the received codeword yₖ.

Having initialized the decoder appropriately, the forward recursion and the backward recursion, as for example defined in Equations 26 to 29, may be performed in steps 705 and 706. In these recursions the exclusion sets Δ_{k,m} and Ω_{k,m} are considered, i.e. only a subset of the values in the distributions αₖ, βₖ and/or Γ(yₖ,Sₖ₋₁,Sₖ) may be used to perform the recursion steps.

Upon having recalculated the new values of αₖ and βₖ, the codeword may be reconstructed by the decoder. This step may for example include the generation of the extrinsic LLR L^{e}(x^{s}ₖ) and an estimation criterion L(dₖ) for deciding upon the individual bits of the decoded codeword \hat{d}ₖ.

In a further embodiment, it may be further possible to reuse the extrinsic LLR L^{e}(x^{s}ₖ) or the estimation criterion L(dₖ) as a parameter for the initialization of the branch transition probabilities Γ(yₖ,Sₖ₋₁,Sₖ) of the next decoding procedure for the subsequent codeword. However, this may facilitate the propagation of decoding errors of a previous codeword to the next codeword.

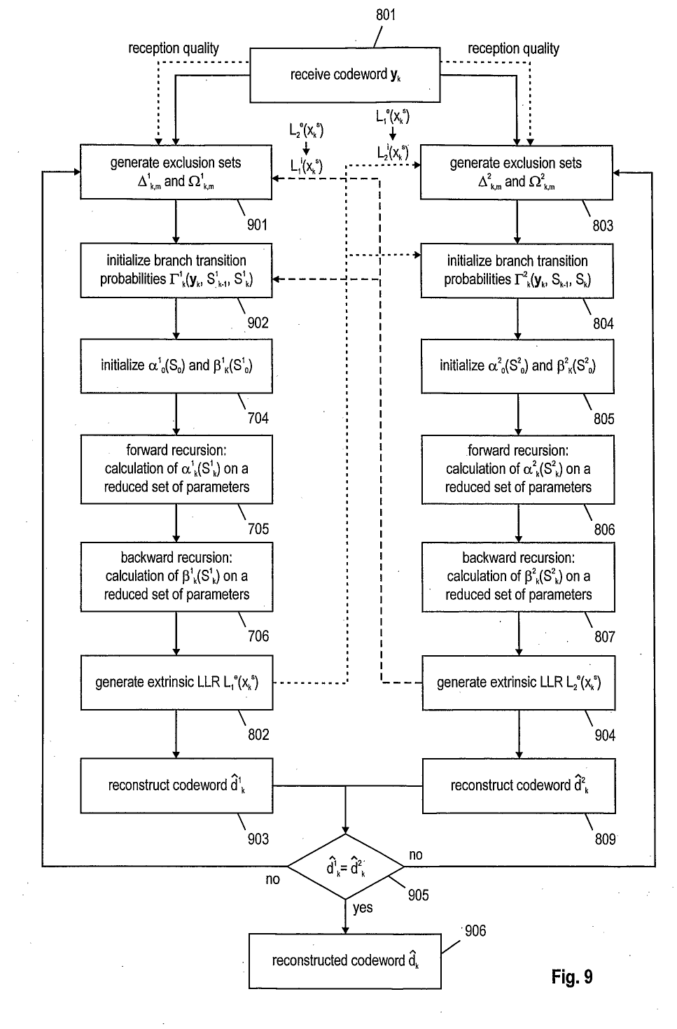

FIGS. 8 and 9 show flowcharts of a decoding process using the turbo principle according to further exemplary embodiments of the present invention. In these examples multiple decoder instances are used in the decoder. For example, such a structure may be application for use with turbo encoders/decoders.

The left branch in the FIGS. 8 and 9 illustrates the operation of a first decoder instance while the right branch illustrates the operation of the second decoder instance. To better differentiate between the parameters of the two different decoder instances, the 1 s and 2 s have been added in superscript or subscript.

Essentially, the steps performed by both decoder instances are similar to the respective steps outlined with reference to FIG. 7. In the following description of FIGS. 8 and 9, it will be therefore focused on the changes applied to the decoding process.

In FIG. 8, a receiving means receives a codeword yₖin step 801 and may provide same to the first decoder instance. Upon generating or obtaining the exclusions sets Δ¹_{k,m} and Ω¹_{k,m} (see step 702), for example using reception quality indicators for the individual bits of a receiving means, the branch transition probabilities Γ¹(yₖ,S¹ₖ₋₁,S¹ₖ) and the values of α¹ₖ and β¹ₖ may be initialized (see steps 703 and 704). Next, the forward recursion step 705 and the backward recursion step 706 are executed.

According to this embodiment of the present invention, the first decoder instance may generate extrinsic LLR L^{e}₁(x^{s}ₖ) (or alternatively an estimation criterion L₁(dₖ) based thereon) in step 802 instead of reconstructing the codeword \hat{d}ₖ. The generated extrinsic LLR L^{e}₁(x^{s}ₖ) (or the estimation criterion L₁(dₖ)) may be forwarded to the second decoder instance for use in its decoding process, which will be explained next.

In step 803 the second decoder instance receives the codeword yₖ from the receiving means. Next, it may generate the exclusions sets Δ²_{k,m} and Ω²_{k,m} or may be provided with same. Alternatively, for example, when using the results of the first decoder instance as indicated by the dotted arrow, the exclusions sets Δ²_{k,m} and Ω²_{k,m} will be generated in step 803. It should be noted that the consideration of the processing results of the first decoder instance is optional in step 803.

Next, the second decoder instance may initialize the branch transition probabilities Γ²(yₖ,S²ₖ₋₁,S²ₖ) in step 804. The extrinsic LLR L^{e}₁(x^{s}ₖ) or the estimation criterion L₁(dₖ) may be used as the intrinsic LLR L¹₂(x^{s}ₖ) in the initialization in the second decoder instance. Further, the values of α²ₖ and β²ₖ are initialized in a similar manner as described for steps 703 and 704.

Upon initializing Γ²(yₖ,S²ₖ₋₁,S²ₖ), α²ₖ and β²ₖ, the forward recursion step 806 and the backward recursion step 807 are executed in a similar manner as described with reference to steps 705 and 706 of FIG. 7.

After having recalculated the probability distributions α²ₖ and β²ₖ the codeword \hat{d}ₖ may be reconstructed. According to the exemplary embodiment of FIG. 8, the extrinsic LLR L^{e}₂(x^{s}ₖ) may be generated next in step 808 and based in these values the codeword \hat{d}ₖ may be reconstructed in step 809.

As has become apparent, the second decoder instance may be operated with a delay relative to the first decoder instance, such that the results of the first decoder instance may be used in the decoding procedure of the second decoder instance. It should also be further noted that in an alternative embodiment the first decoder instance may reconstruct a decoded codeword which may be compared to same obtained from the second decoder instance. In this case, the second decoder may or may not be operated delayed to the first decoder instance. This process will be more closely described in reference to FIG. 9 in the following.

FIG. 9 shows a flowchart of a decoding process using the turbo principle according to a further exemplary embodiment of the present invention. The decoding processes in the two decoder instances shown in the left and right branches of FIG. 9 are almost identical. The first decoding iteration in the first decoder instance is similar to the one explained with reference to FIG. 8, i.e. for the first decoding iteration steps 901 and 902 are similar to steps 702 and 703 in FIGS. 7 and 9.

Upon initialization and the calculations of the forward recursion an backward recursion (see steps 704, 705, 706), the first decoder instance generates an extrinsic LLR L^{e}₁(x^{s}ₖ) which is provided to the second encoder instance. Further, the first decoding instance construct the decode codeword \hat{d}¹ₖ.

In parallel or with a delay allowing the use of the results of the first decoder instance in step 804 (and optionally step 803), the second decoder instance may perform (steps 803 to 807, 809 and 904) a similar decoding as the first decoder instance or a decoding iteration as described with reference to the second decoder instance in FIG. 8.

At the end of the first decoding iteration, the second decoding instance generates a reconstructed codeword \hat{d}²ₖ. In step 905, the two generated codeword \hat{d}¹ₖ and \hat{d}²ₖ are compared and if found to be equal the decoding process finishes in step 906.

If however the decision in step 905 comes to a negative result, a further decoding iteration may be performed. In this case the second decoder instance may provide its extrinsic LLR L^{e}₂(x^{s}ₖ) to the first decoder instance (step 904) as indicated by the dotted arrows. Similar to the second decoder instance, the first decoder instance may use this extrinsic information as an intrinsic information, e.g. the intrinsic LLR Lⁱ₁(x^{s}ₖ), in the decoding iteration. I.e. the information of the second decoder instance may be used for obtaining a newly initialized set of branch transition probabilities Γ¹(yₖ,S¹ₖ₋₁,S¹ₖ) in step 902 and, optionally, for determining the new exclusion sets Δ¹_{k,m} and Ω¹_{k,m} in step 901.

Thus, the decoder may perform several iterations before obtaining similar reconstructed codewords \hat{d}¹ₖ and \hat{d}²ₖ, which will end the decoding procedure for received codeword yₖ. Further, in case the reconstructed codewords \hat{d}¹ₖ and \hat{d}²ₖ do not match after a predetermined number of iterations, the decoding process may be halted and a decoding error may be signaled to the next processing instance.

Though the exemplary decoding procedure of FIG. 9 has been described with both decoder instances reconstructing a codeword and comparing same, it should be noted that also a procedure as proposed in the embodiment shown in FIG. 8 may be employed together with performing several decoding iterations before reconstructing the codeword.

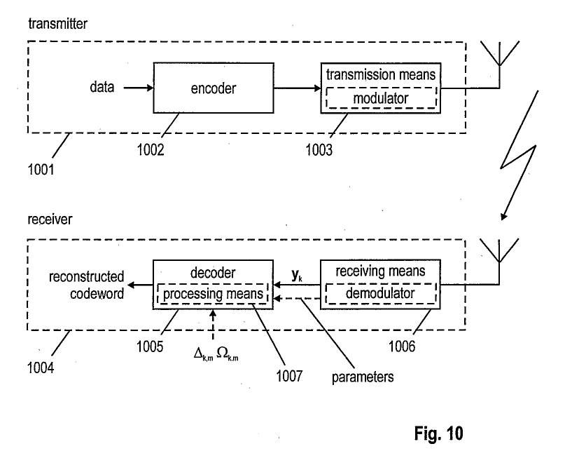

Next, FIG. 10 will be discussed in more detail. FIG. 10 shows a transmitter and a receiver unit according to an embodiment of the present invention. The transmitter 1001 comprises an encoder 1002 and a transmission means 1003. The transmission means may comprise a modulator for modulating the signals encoded by encoder 1002. As indicated by the dotted arrow, the encoder 1002 is capable of encoding input data into codeword suitable for decoding according to the various embodiments of the decoding process described above. The modulated data may be transmitted by the transmission means 1003 using an antenna as indicated.

The receiver 1004 receiving the encoded signals may comprise a receiving means 1006, which may comprise a demodulator for demodulating the received signals. Upon extracting the yₖ values and parameters such as the transmission quality or a reliability criterion for each bit in received codeword yₖ in the receiving means 1006, these data may be provided to a decoder 1005, which will consider the data to initialize the decoding process as outlined above.

The decoder 1005 may comprise a processing means 1007, adapted to decode the received data according to the methods described above to produce reconstructed codewords.

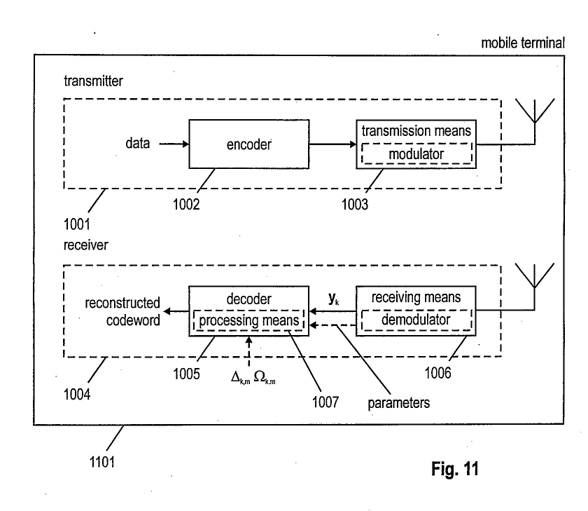

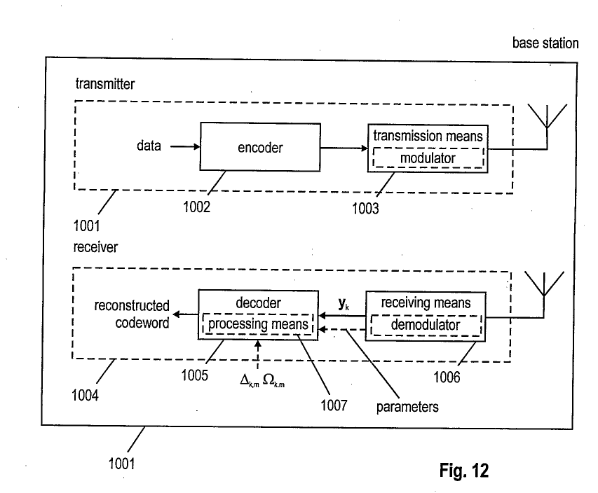

FIGS. 11 and 12 show a mobile terminal (UE) 1101 and a base station (Node B) 1201 according to different embodiments of the present invention, respectively. The mobile terminal 1101 and the base station may each include a transmitter 1001 and a receiver 1004 as shown in FIG. 10 to perform communications.

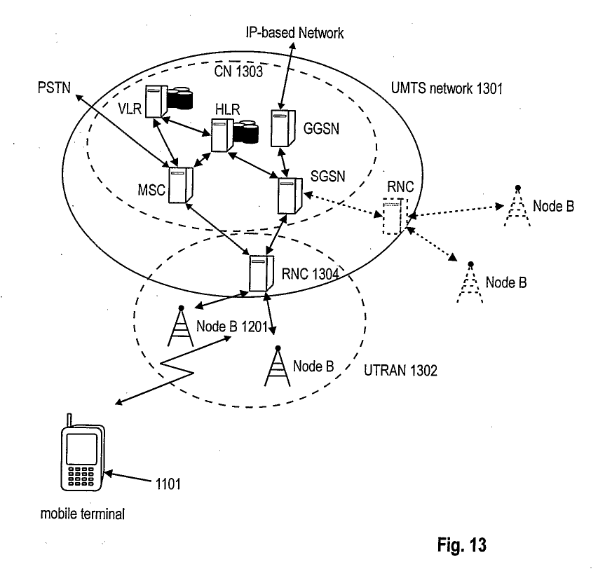

FIG. 13 shows an architectural overview of a communication system according to an embodiment of the present invention comprising a mobile terminal 1101 shown in FIG. 11 and a base station (Node B) 1201 shown in FIG. 12.

The overview depicts a UMTS network 1301, which comprises a core network (CN) 1303 and the UMTS terrestrial radio access network (UTRAN) 1302. The mobile terminal 1101 may be connected to the UTRAN 1302 via a wireless link to a Node B 1201. The base stations in the UTRAN 1302 may be further connected to a radio network controller (RNC) 1304. The CN 1303 may comprise a (Gateway) Mobile Switching Center (MSC) for connecting the CN 1303 to a Public Switched Telephone Network (PSTN). The Home Location Register (HLR) and the Visitor Location Register (VLR) may be used to store user related information. Further, the core network may also provide connection to an Internet Protocol-based (IP-based) network through the Serving GPRS Support Node (SGSN) and the Gateway GPRS Support Node (GGSN).

Though exemplary reference to a mobile communication system has been made above, those skilled in the art will notice that the present invention may also be applicable for use in wireless (data) networks, as for example IEEE 802.11, digital video broadcasting, such as DVB, or digital audio broadcasting, as for example DAB or DRM.

1-16. (canceled)

17. A method for decoding in a decoder at least one codeword, wherein the at least one codeword has been generated by an encoder comprising a structure providing a code representable by a set of branch transitions in a trellis diagram, the method comprising:
a) initializing a set of branch transition probabilities in the decoder based on the received codeword and the encoder structure;
b) initializing a first probability distribution and a second probability distribution according to the initial state of the encoder used to encode the at least one codeword;
c) recalculating the values of the first probability distribution based on the initial values of the first probability distribution and the set of branch transition probabilities using a recursive algorithm;
d) recalculating the values of the second probability distribution based on the initial values of the second probability distribution and the set of branch transition probabilities using a recursive algorithm; and
e) reconstructing a decoded codeword based on the received codeword and an extrinsic probability measure calculated based on the set of branch transition probabilities, the first and the second probability distribution;
wherein in either each of or both steps c) and d) a subset of initial values of the first probability distribution or the second probability distribution, respectively, and a subset of the set of branch transition probabilities is used for recalculating the respective probability distribution, and wherein the values in the subsets fulfill a predetermined reliability criterion.

18. The method according to claim 17, wherein the encoder is representable by a shift register structure containing at least one of feed-forward mathematic operations and feed-back mathematic operations.

19. The method according to claim 17, wherein the code is suitable for decoding by employing a maximum a-posteriori algorithm.

20. The method according to claims 17, by further comprising using an intrinsic probability measure to initialize the set of branch transition probabilities in step a).

21. The method according to claim 17, further comprising using an intrinsic probability measure to reconstruct the decoded codeword in step e).

22. The method according to claim 20, wherein a decoder representable by two separate decoder instances is used for decoding the at least one codeword in a first decoding step and
the method further comprises using the extrinsic probability measure of the first decoder instance as the intrinsic probability measure in the second decoder instance.

23. The method according to claim 22, further comprising performing a second decoding iteration comprising steps a) to e) in the first decoder instance, and
wherein the first decoder instance uses the extrinsic probability measure of the second decoder instance as the intrinsic probability measure.

24. The method according to claim 17, wherein the reliability criterion is based on at least one of channel estimations of a radio channel via which the at least one codeword has been received, the absolute values of the elements of the first and/or second probability distribution, the number of decoding steps performed and a random process.

25. The method according to claim 24, wherein the reliability criterion is not fulfilled by an element of the first or the second probability distribution, if the signal to noise ratio for the element and/or the absolute value of the element is below a predetermined threshold value.

26. A decoder for decoding at least one codeword, wherein the at least one codeword has been generated by an encoder comprising a structure providing a code representable by a set of branch transitions in a trellis diagram, the decoder comprising processing unit configured to:
a) initialize a set of branch transition probabilities in the decoder based on the received codeword and the encoder structure;
b) initialize a first probability distribution and a second probability distribution according to the initial state of the encoder used to encode the at least one codeword;
c) recalculate the values of the first probability distribution based on the initial values of the first probability distribution and the set of branch transition probabilities using a recursive algorithm;
d) recalculate the values of the second probability distribution based on the initial values of the second probability distribution and the set of branch transition probabilities using a recursive algorithm; and
e) reconstruct a decoded codeword based on the received codeword and an extrinsic probability measure calculated based on the set of branch transition probabilities, the first and the second probability distribution;
wherein the processing unit is configured to use in either each of or both steps c) and d) a subset of initial values of the first probability distribution or the second probability distribution, respectively, and a subset of the set of branch transition probabilities for recalculating the respective probability distribution, and
wherein the values in the subsets fulfill a predetermined reliability criterion.

27. A mobile terminal in a mobile communication system, comprising:
receiving unit configured to receive at least one codeword, demodulation unit configured to demodulate the at least one received codeword, and
a decoder according to claim 26.

28. The mobile terminal according to claim 27, further comprising an encoding unit configured to encode data in at least one codeword, and a transmission unit configured to transmit the at least one codeword, and wherein at least one transmitted codeword is suitable for decoding according to a method wherein the at least one transmitted codeword has been generated by an encoder comprising a structure providing a code representable by a set of branch transitions in a trellis diagram, the method comprising:
a) initializing a set of branch transition probabilities in the decoder based on the received codeword and the encoder structure;
b) initializing a first probability distribution and a second probability distribution according to the initial state of the encoder used to encode the at least one codeword;
c) recalculating the values of the first probability distribution based on the initial values of the first probability distribution and the set of branch transition probabilities using a recursive algorithm;
d) recalculating the values of the second probability distribution based on the initial values of the second probability distribution and the set of branch transition probabilities using a recursive algorithm; and
e) reconstructing a decoded codeword based on the received codeword and an extrinsic probability measure calculated based on the set of branch transition probabilities, the first and the second probability distribution;
wherein in either each of or both steps c) and d) a subset of initial values of the first probability distribution or the second probability distribution, respectively, and a subset of the set of branch transition probabilities is used for recalculating the respective probability distribution, and wherein the values in the subsets fulfill a predetermined reliability criterion.

29. A base station in a mobile communication system, comprising:
receiving unit configured to receive at least one codeword,
demodulation unit configured to demodulate the at least one received codeword, and
a decoder according to claim 26.

30. The base station terminal according to claim 29, further comprising an encoding unit configured to encode data in at least one codeword, and a transmission unit configured to transmit the at least one codeword, and wherein at least one transmitted codeword is suitable for decoding according to a method wherein the at least one transmitted codeword has been generated by an encoder comprising a structure providing a code representable by a set of branch transitions in a trellis diagram, the method comprising:
a) initializing a set of branch transition probabilities in the decoder based on the received codeword and the encoder structure;
b) initializing a first probability distribution and a second probability distribution according to the initial state of the encoder used to encode the at least one codeword;
c) recalculating the values of the first probability distribution based on the initial values of the first probability distribution and the set of branch transition probabilities using a recursive algorithm;
d) recalculating the values of the second probability distribution based on the initial values of the second probability distribution and the set of branch transition probabilities using a recursive algorithm; and
e) reconstructing a decoded codeword based on the received codeword and an extrinsic probability measure calculated based on the set of branch transition probabilities, the first and the second probability distribution;
wherein in either each of or both steps c) and d) a subset of initial values of the first probability distribution or the second probability distribution, respectively, and a subset of the set of branch transition probabilities is used for recalculating the respective probability distribution, and
wherein the values in the subsets fulfill a predetermined reliability criterion.

31. A mobile communication system comprising at least one base station according to claim 29 and at least one mobile terminal, comprising:
a receiving unit configured to receive at least one codeword,
a demodulation unit configured to demodulate the at least one received codeword, and
a decoder configured to decode at least one codeword, wherein the at least one codeword has been generated by an encoder comprising a structure providing a code representable by a set of branch transitions in a trellis diagram, the decoder comprising processing unit configured to:
a) initialize a set of branch transition probabilities in the decoder based on the received codeword and the encoder structure;
b) initialize a first probability distribution and a second probability distribution according to the initial state of the encoder used to encode the at least one codeword;
c) recalculate the values of the first probability distribution based on the initial values of the first probability distribution and the set of branch transition probabilities using a recursive algorithm;
d) recalculate the values of the second probability distribution based on the initial values of the second probability distribution and the set of branch transition probabilities using a recursive algorithm; and
e) reconstruct a decoded codeword based on the received codeword and an extrinsic probability measure calculated based on the set of branch transition probabilities, the first and the second probability distribution;
wherein the processing unit is configured to use in either each of or both steps c) and d) a subset of initial values of the first probability distribution or the second probability distribution, respectively, and a subset of the set of branch transition probabilities for recalculating the respective probability distribution, and
wherein the values in the subsets fulfill a predetermined reliability criterion.
